(19) United States
(12) Patent Application Publication
(10) Pub. No.: US 2026/0171114 A1
(43) Pub. Date: Jun. 18, 2026

(54) FORMING A WRITE POLE USING AN OXIDIZATION RESISTANT SEED LAYER

(71) Applicant: SEAGATE TECHNOLOGY LLC, Fremont, CA (US)

(72) Inventors: Joseph Roth, Minneapolis, MN (US); Jie Gong, Eden Prairie, MN (US)

(21) Appl. No.: 18/978,439

(22) Filed: Dec. 12, 2024

(51) Int. Cl. G11B 5/31; C23F 17/00; C25D 5/34; C25D 5/50

(52) U.S. Cl. CPC G11B 5/3163; C23F 17/00; C25D 5/34; C25D 5/50

(57) ABSTRACT

Described are methods of forming write poles using physical vapor deposition or chemical vapor deposition of FeCoX magnetic material alloys, where the X element is selected to produce properties such as oxidation resistance, corrosion resistance, and sufficiently high magnetic moment. Once an initial portion of the write pole is formed by depositing the FeCoX alloy, the remainder of the write pole may be formed by electroplating an FeCo-based alloy using the deposited FeCoX as an electroplating template, or by deposition of additional FeCoX material to form the bulk of the write pole.

### TECHNICAL FIELD

The disclosure relates to materials for forming write poles for use in magnetic writers.

### SUMMARY

In accordance with various aspects, the present disclosure describes methods for making a magnetic writer having a write pole. Such methods include depositing an FeCoX alloy using physical vapor deposition techniques to thereby form an initial portion of the write pole, where X is selected to increase resistance to oxidation relative to FeCo while maintaining a magnetic moment of 2 T or greater. A remaining portion of the write pole is then formed on the initial portion of the write pole, and the write pole is incorporated into the magnetic writer. Forming the remaining portion of the write pole may include depositing the FeCoX alloy using physical vapor deposition techniques or chemical vapor deposition techniques, or may include electroplating an FeCo-based alloy using the initial portion of the write pole as a seed for the electroplating.

In certain aspects, the X element of the FeCoX alloy is Ir, Cr, Ni, Rh, Re, Ru, Pd, Os, Zn, Ge, or Sn.

In certain aspects, depositing the FeCoX alloy includes sputtering a single FeCoX target, or co-sputtering an FeCo target and a target composed of the X element.

In certain aspects, the write pole has a magnetic moment of 2.3 T or greater.

In certain aspects, the FeCoX alloy is FeCoIr and includes Ir in an amount of about 3% by atomic weight to about 7% by atomic weight.

In certain aspects, the FeCoX alloy is FeCoCr and includes Cr in an amount of about 6% by atomic weight or less.

In certain aspects, the FeCoX alloy is FeCoRh and includes Rh in an amount of about 6% by atomic weight or less.

In accordance with various aspects, the present disclosure describes methods for making a magnetic writer having a write pole. Such methods include depositing an FeCoIr alloy to thereby form an initial portion of the write pole, electroplating an FeCo-based alloy using the initial portion of the write pole as a seed for the electroplating to thereby form a remaining portion of the write pole, and incorporating the write pole into the magnetic writer. The FeCoIr alloy may include Ir in an amount of about 3% by atomic weight to about 7% by atomic weight, and Fe in an amount of less than about 70% by atomic weight. The electroplated FeCo-based alloy may be FeCo, FeCoIr, FeCoCr, FeCoNi, FeCoRh, FeCoRe, FeCoOs, FeCoZn, FeCoGe, or FeCoZn.

In certain aspects, annealing may be performed on the initial portion of the write pole after depositing the FeCoIr alloy and before electroplating the FeCo-based alloy, and/or annealing may be performed after electroplating the FeCo-based alloy.

In certain aspects, the magnetic writer may be incorporated into a hard disk drive such as a HAMR hard disk drive.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1 is a schematic representation of a hard disk drive that may incorporate a writer having a write pole made using materials and methods in accordance with aspects of the present disclosure.

FIG. 2 is a schematic cut-away perspective view of components of a writer that includes a write pole that may be formed using materials and methods in accordance with aspects of the present disclosure.

FIG. 3 is a flow chart depicting steps that may be performed in depositing materials during the formation of a write pole in accordance with certain aspects of the present disclosure.

### DETAILED DESCRIPTION

The present disclosure relates to forming write poles using materials and techniques that result in the write poles being suitable for incorporation into magnetic writers that may be subject to elevated temperatures or other harsh conditions such as may be found in hard disk drives that employ heat-assisted magnetic recording (HAMR). In particular, the present disclosure relates to the deposition of FeCoX magnetic material alloys, where the X element is selected to produce properties such as oxidation resistance, corrosion resistance, and sufficiently high magnetic moment, and where the FeCoX alloy may be used to form the bulk of the write pole and/or as a template for electroplating a material that forms the bulk of the write pole.

FeCo-based magnetic materials are used in many industrial applications, including in the magnetic recording industry where they are typically used to form write poles as part of a magnetic writers (also referred to herein as a write head or write transducer) for hard disk drives (HDDs). When incorporated into writers for HAMR hard drives, write poles may be subjected to elevated temperatures and other extreme conditions during processing and/or operation, and particularly at the air-bearing surface (ABS) of the recording head into which the write poles are incorporated. As such, the write pole material desirably has a high oxidation resistance to thereby reduce oxidation and corrosion that may otherwise deteriorate the performance of the device. The write pole material preferably exhibits a high magnetic moment and other desirable magnetic properties (such as softness, coercivity, and anisotropy), as well as being able to meet certain wafer processing and operational requirements.

While various electroplated FeCo-based alloys have been shown to meet certain of these requirements, preparing suitable seed layers as electroplating templates has been difficult, particularly in achieving desirable anti-oxidation and anti-corrosion properties without concurrently reducing magnetic properties such as magnetic moment. As such, it is recognized in the present disclosure that there is a need for FeCoX materials and deposition methodologies for forming write poles and/or for providing an initial seed template for electroplating an FeCo-based alloy for forming write poles, and in which the FeCoX material meets the same or similar requirements for oxidation resistance and magnetic moment as current write pole materials. Moreover, the FeCoX materials and deposition techniques are preferably compatible with efficient wafer processing and fabrication.

In accordance with various aspects, FeCoX alloys may be formed by alloying a few atomic percent of transition metals as the “X” element, such elements including Ir, Cr, Ni, Rh, Re, Ru, Pd, Os, Zn, Ge, Sn, and so forth, to thereby significantly increase resistance to oxidation and corrosion. While the addition of a third element into an FeCo alloy often leads to a rapid decrease in magnetic properties, in accordance with aspects of the present disclosure certain elements may be selected that maintain favorable magnetic properties required for usage in a write pole of a magnetic writer. The ability to deposit such materials using physical vapor deposition (PVD) techniques such as sputtering, or using chemical vapor deposition (CVD) techniques, allows these materials to be applied to form a seed template for electroplating materials to form the remainder of the write pole, or to be applied in bulk to directly form the write pole. Moreover, the use of PVD or CVD techniques can allow for high deposition rates, a high degree of thickness control, and excellent control of stoichiometry of the alloy being deposited. This may be beneficial both for ease of manufacturing as well as for rapidity and repeatability of testing, screening, and tuning of materials and alloying concentrations of FeCo materials with other elements.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements.

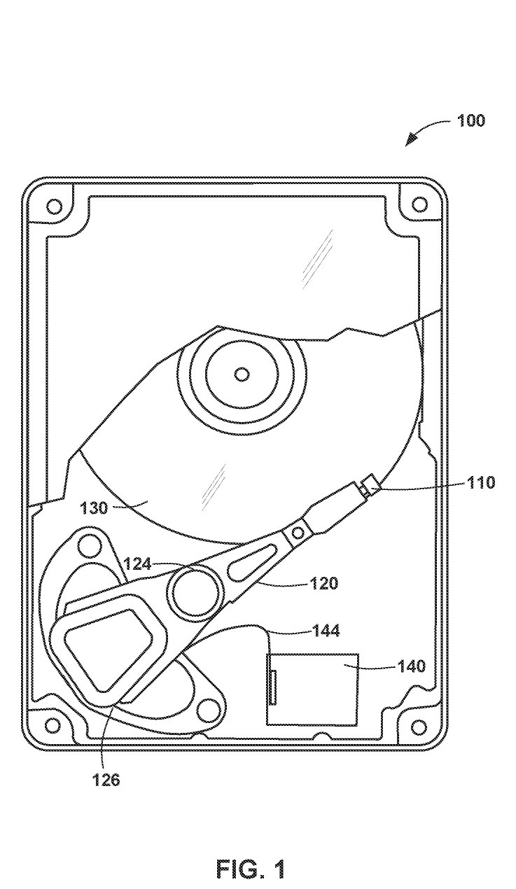

FIG. 1 schematically depicts an example HDD device 100 that includes a slider 110 that typically incorporates both a magnetic reader and a magnetic writer, which may be collectively referred to as a recording head. Slider 110 is disposed on the end of an actuator arm 120 that is rotationally movable around a pivot 124 by use of a voice coil motor 126. The slider 110 is positioned in close proximity to the surface of magnetic media disk 130 such that the writer can write data to tracks on the magnetic media 130 and the reader can read data from tracks on the magnetic media 130 as the media spins under the slider 110 by action of a spindle motor (not indicated). The writer portion of slider 110 may include a write pole made using materials and methods in accordance with various aspects of the present disclosure.

Controller electronics 140 may be coupled to the voice coil motor 126 and to components of the slider 110 via a flex cable 144 that connects to traces on the actuator 120. Preamp electronics (not indicated) are typically disposed on or close to the slider 110 for conditioning signals to and from the recording head. Controller electronics 140 may also be communicatively coupled to spindle motor 135 to thereby control the spinning of the media disk(s) 130, along with the movement of the actuator 120 and the reading and writing of data. The internal components of HDD 100 are contained within an enclosure, which includes a cover that is shown partially cut away to reveal the internal components. A host device can communicate with HDD 100 through a standardized interface (not shown). HDD 100 can operate on any magnetic recording principle, whether that be conventional magnetic recording (CMR), shingled magnetic recording (SMR), heat-assisted magnetic recording (HAMR), or any other type of recording technique, including combinations thereof. As used in the present disclosure, the term HAMR refers broadly to any energy-assisted magnetic recording technique.

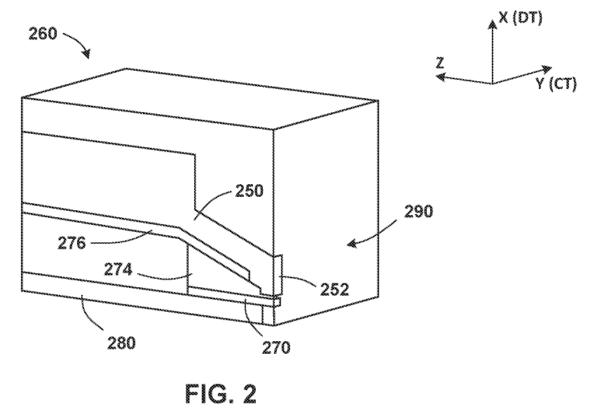

FIG. 2 schematically shows a cut-away perspective view of certain components of a magnetic writer 260, including a write pole 250 incorporated into the magnetic writer 260. The write pole 250 includes a write pole tip 252 that extends to an air-bearing surface (ABS) 290 of the writer 260. The orthogonal x-y-z axes in FIG. 2 indicate the orientation of writer 260 relative to its magnetic recording functionality. As such, the x-axis and y-axis are in the plane of the ABS 290 of writer 260, with the x-axis being aligned to the down-track (DT) direction, which is direction of motion of the magnetic media (not shown) relative to the writer 260, and the y-axis being aligned to the cross-track (CT) direction. The z-axis is then aligned to the direction perpendicular to the ABS 290, and which defines the spacing between the recording head and the media. Writer 260 may include additional components such as a near-field transducer 270 for generating and focusing plasmons on the surface of the magnetic media to assist in recording. A waveguide 280 may deliver electromagnetic radiation, such as from a laser (not shown), to the near-field transducer 270. A heat sink 274 and heat diffuser 278 may be used to transport excess heat away from the ABS 290 and components such as the near-field transducer 270 and write pole tip 252. Incorporating write pole 250 into writer 260 can be done using any suitable techniques, including film growth, electroplating, and various patterning techniques.

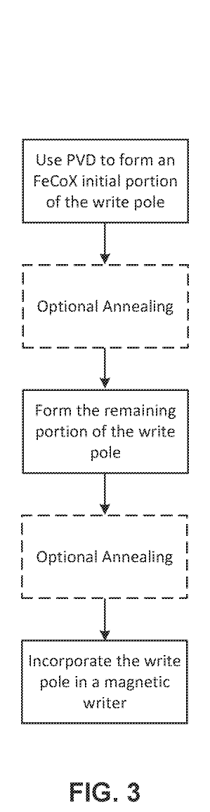

FIG. 3 shows steps in forming a write pole in accordance with various aspects of the present disclosure. Deposition techniques such as PVD or CVD are used to form an FeCoX alloy. The deposition may take place on any suitable substrate, for example on a silicon or silicon oxide substrate. To deposit the FeCoX alloy via PVD, an FeCoX target may be sputtered. Alternatively, two targets may be sputtered, one including FeCo and the other including the X element. By co-sputtering two different targets, it may be possible to fine tune the stoichiometry of the resulting FeCoX alloy. In various embodiments, the X element may be any transition element that promotes protection against oxidation and corrosion and that maintains the magnetic moment of the FeCo alloy or otherwise results in an insubstantial loss in magnetic moment. Suitable elements include Ir, Cr, Ni, Rh, Re, Ru, Pd, Os, Zn, Ge, and Sn. The amount of the X element present in the FeCoX alloy may be tuned to provide a desired amount of resistance to oxidation and corrosion as well as a desired magnetic moment. Preferably the magnetic moment is 2 T or greater, more preferably 2.3 T or greater.

Oxidation kinetics may be used to determine resistance to oxidation, and in particular by measuring the atomic percent of oxidation in the top 50 nm of a layer of FeCoX when the layer is annealed at 250 degrees C in air. In certain embodiments, it may be preferred that the atomic percent of oxidized moieties in the top 50 nm after annealing at 250 degrees C for 4 hours is less than about 40%, preferably less than about 35%, and more preferably less than about 30%. It has been observed that such results may be achieved using X = Ir, Rh, and Cr, among other materials. In particular, when X is Ir, forming FeCoIr stoichiometries where Ir is present in an amount of about 3% atomic weight to about 7% atomic weight exhibit sufficiently low oxidation and corrosion after annealing in air for 4 hours at 250 degrees C.

For write pole applications in HAMR hard drives, the FeCoX material that serves as the initial portion of the write pole during write pole formation preferably exhibits a magnetic moment that remains at or above about 2 T, and more preferably at or above 2.3 T. For X = Ir, a magnetic moment above 2.3 T is maintained for all concentrations of Ir tested up to 7% atomic weight. Magnetic moments around 2.3 T or more were also observed for FeCoX alloys for X = Cr at concentrations below 6% atomic weight, and for X = Rh at concentrations below 6% atomic weight. These magnetic properties compare favorably to various electroplated FeCo-based alloys, and each of the alloys FeCoIr, FeCoCr, and FeCoRh can function as a seed template for electroplating FeCo-based alloys, or can be deposited in bulk to form the entire write pole.

Referring back to FIG. 3, after forming an initial portion of the write pole by depositing FeCoX, the remaining portion of the write pole may be formed. This can take place by electroplating an FeCo-based alloy, using the initial portion of the write pole as a seed template. When electroplating an FeCo-based alloy to form the remaining portion of the write pole, the FeCo-based alloy is preferably an alloy of FeCo, FeCoIr, FeCoCr, FeCoNi, FeCoRh, FeCoRe, FeCoOs, FeCoZn, FeCoGe, or FeCoZn. The inclusion of an additional element to the FeCo-based alloy may provide for oxidation and corrosion resistance in the electroplated portion, similar to in the vapor deposited portion, while maintaining desired magnetic properties. Alternatively, the same FeCoX material deposited as the initial layer can be deposited in bulk to form the remaining portion of the write pole. Formation and patterning of the portions of the write pole can take place using any suitable techniques, including standard techniques that are currently known and used. Optionally, annealing can be performed after formation of the initial portion of the write pole and/or after forming the remaining portion of the write pole. Annealing may promote improvement of magnetic properties such as softness, coercivity, and anisotropy. The write pole, when formed, may be incorporated into the magnetic writer in the same way that other write poles are incorporated.

By using methods exemplified in the present disclosure, a write pole can be formed suitable for incorporation in a magnetic writer that has sufficient resistance to oxidation and the retains sufficient magnetic moment and other magnetic properties. Such methods include co-sputtering two targets to alloy FeCo with an element X to form a portion that can be used as a seed for FeCo electroplating (where FeCo may include any suitable FeCo allowy). Such methods further include physical vapor deposition of a composite target of FeCoX to use as a seed for FeCo electroplating. Such methods further include two-target or single-target physical vapor deposition of FeCoX to form the entire write pole. In these embodiments, the element X may be, for example, Ir, Cr, Rh, Re, Ru, Pd, Os, Zn, Ge, Sn, and so forth. In accordance with various aspects of the present disclosure, the addition of low doping concentrations of such transition metals can increase resistance to oxidation and/or corrosion without substantial loss of magnetic moment. For example, less than about 10% by atomic weight of such transition metals may be alloyed to FeCo, and preferably less than about 7% by atomic weight of Ir, Cr, or Rh may be alloyed to FeCo.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (for example, all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

All scientific and technical terms used herein have meanings commonly used in the art unless otherwise specified. The definitions provided herein are to facilitate understanding of certain terms used frequently herein and are not meant to limit the scope of the present disclosure.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality.

As used herein, any term related to position or orientation, such as “proximal,” “distal,” “end,” “outer,” “inner,” and the like, refers to a relative position and does not limit the absolute orientation of an embodiment unless its context of usage clearly dictates otherwise.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,” and the like are subsumed in “comprising,” and the like.

Reference to “one embodiment,” “an embodiment,” “certain embodiments,” or “some embodiments,” etc., means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. A method for making a magnetic writer having a write pole, the method comprising:
depositing an FeCoIr alloy using physical vapor deposition techniques or chemical vapor deposition techniques to thereby form an initial portion of the write pole;
electroplating an FeCo-based alloy using the initial portion of the write pole as a seed for the electroplating to thereby form a remaining portion of the write pole; and
incorporating the write pole into the magnetic writer.

2. The method of claim 1, wherein the FeCoIr alloy includes Ir in an amount of about 3% by atomic weight to about 7% by atomic weight, and Fe in an amount of less than about 70% by atomic weight.

3. The method of claim 1, wherein depositing the FeCoIr alloy comprises sputtering a single FeCoIr target.

4. The method of claim 1, wherein depositing the FeCoIr alloy comprises co-sputtering an FeCo target and an Ir target.

5. The method of claim 1, wherein the write pole has a magnetic moment of 2 T or greater.

6. The method of claim 1, wherein the write pole has a magnetic moment of 2.3 T or greater.

7. The method of claim 1, further comprising annealing the initial portion of the write pole after depositing the FeCoIr alloy and before electroplating the FeCo alloy.

8. The method of claim 1, further comprising annealing the write pole after electroplating the FeCo-based alloy.

9. The method of claim 1, further comprising incorporating the magnetic writer into a hard disk drive.

10. The method of claim 9, wherein the hard disk drive is a HAMR hard disk drive.

11. A method for making a magnetic writer having a write pole, the method comprising:
depositing an FeCoX alloy to thereby form an initial portion of the write pole, wherein X is selected to increase resistance to oxidation relative to FeCo while maintaining a magnetic moment of 2 T or greater;
forming a remaining portion of the write pole on the initial portion of the write pole; and
incorporating the write pole into the magnetic writer.

12. The method of claim 11, wherein forming the remaining portion of the write pole comprises depositing the FeCoX alloy using physical vapor deposition techniques.

13. The method of claim 11, wherein forming the remaining portion of the write pole comprises electroplating an FeCo-based alloy using the initial portion of the write pole as a seed for the electroplating.

14. The method of claim 13, wherein electroplating an FeCo-based alloy comprises electroplating FeCo, FeCoIr, FeCoCr, FeCoNi, FeCoRh, FeCoRe, FeCoOs, FeCoZn, FeCoGe, or FeCoZn.

15. The method of claim 11, wherein X comprises Ir, Cr, Ni, Rh, Re, Ru, Pd, Os, Zn, Ge, or Sn.

16. The method of claim 11, wherein depositing the FeCoX alloy comprises using physical vapor deposition techniques or chemical vapor deposition techniques.

17. The method of claim 11, wherein the write pole has a magnetic moment of 2.3 T or greater.

18. The method of claim 11, wherein the FeCoX alloy is FeCoIr and includes Ir in an amount of about 3% by atomic weight to about 7% by atomic weight.

19. The method of claim 11, wherein the FeCoX alloy is FeCoCr and includes Cr in an amount of about 6% by atomic weight or less.

20. The method of claim 11, wherein the FeCoX alloy is FeCoRh and includes Rh in an amount of about 6% by atomic weight or less.
